(19) United States
(12) Patent Application Publication
(10) Pub. No.: US 2026/0136916 A1
(43) Pub. Date: May 14, 2026

(54) SEMICONDUCTOR STRUCTURE WITH CONDUCTIVE THROUGH VIA AND A METHOD OF MANUFACTURING THE SAME

(71) Applicant: TAIWAN SEMICONDUCTOR MANUFACTURING COMPANY LTD., HSINCHU (TW)

(72) Inventors: HWEI-JAY CHU, HSINCHU CITY (TW); HSI-WEN TIEN, HSINCHU COUNTY (TW); WEI-HAO LIAO, TAICHUNG CITY (TW); YU-TENG DAI, NEW TAIPEI CITY (TW); HSIN-CHIEH YAO, HSINCHU CITY (TW); CHENG-HAO CHEN, KAOHSIUNG CITY (TW); WEI CHIH WANG, HSINCHU (TW); CHIH WEI LU, HSINCHU CITY (TW)

(21) Appl. No.: 18/940,890

(22) Filed: Nov. 8, 2024

(51) Int. Cl. H01L 23/528; H01L 21/768; H01L 23/522

(52) U.S. Cl. CPC H10W 20/435; H10W 20/057; H10W 20/089; H10W 20/42

(57) ABSTRACT

The present disclosure provides a semiconductor structure. The semiconductor structure includes: a conductive layer, disposed over a substrate; a first conductive structure, disposed over the conductive layer; an isolating member, disposed over the conductive layer and separated from the first conductive structure, wherein the first conductive structure and the isolating member are surrounded by a first dielectric layer; a first conductive member, disposed on isolating member; and a second conductive member, disposed on the first conductive structure and the first dielectric layer. The first conductive member and the first conductive structure extend along a first direction. The second conductive member extends along a second direction perpendicular to the first direction.

### BACKGROUND

A damascene metallization process forms conductive interconnects by deposition of conductive metals, i.e., copper or copper alloy, in via holes or trenches formed in a semiconductor wafer. However, use of copper has a disadvantage of high diffusivity in common dielectric materials such as silicon oxide, which causes corrosion of the copper with attendant serious problems of loss of adhesion, delamination, and consequent electrical failure of circuitry. Therefore, a barrier layer is required for the copper interconnects.

However, use of the barrier layer increases electrical resistance of the copper interconnects. Therefore, there is a need to improve semiconductor processes for forming semiconductor devices with improved performance.

### BRIEF DESCRIPTION OF THE DRAWINGS

Aspects of embodiments of the present disclosure are best understood from the following detailed description when read with the accompanying figures. It should be noted that, in accordance with standard practice in the industry, various structures are not drawn to scale. In fact, dimensions of the various structures can be arbitrarily increased or reduced for clarity of discussion.

FIG. 1 is a flow diagram showing a method for forming a semiconductor structure with conductive through vias, in accordance with some embodiments of the present disclosure.

FIGS. 2 to 30B are schematic cross-sectional and top views illustrating sequential operations of the method in FIG. 1 to form a semiconductor structure with conductive through vias, in accordance with some embodiments of the present disclosure.

### DETAILED DESCRIPTION OF THE DISCLOSURE

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In some embodiments, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass orientations of the device in use or operation in some embodiments different from the orientation depicted in the figures. The apparatus may be otherwise oriented (rotated 90 degrees or at other orientations) and the spatially relative descriptors used herein may likewise be interpreted accordingly.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the normal deviation found in the respective testing measurements. Also, as used herein, the terms “substantially,” “approximately” and “about” generally mean within a value or range which can be contemplated by people having ordinary skill in the art. Alternatively, the terms “substantially,” “approximately” and “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of time, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

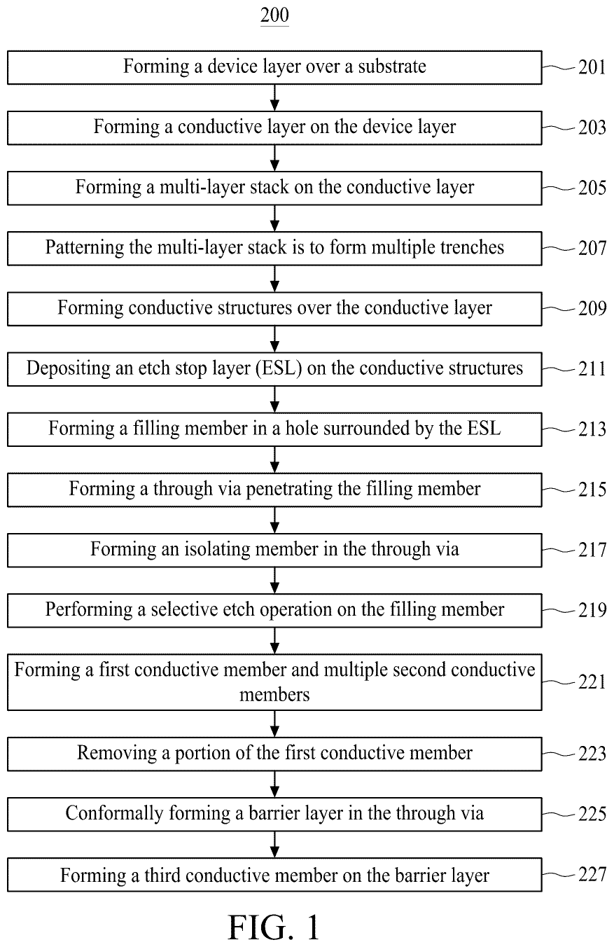

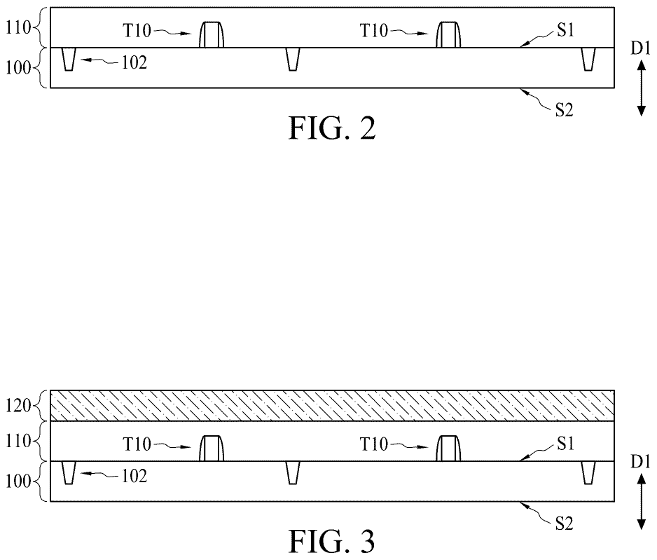

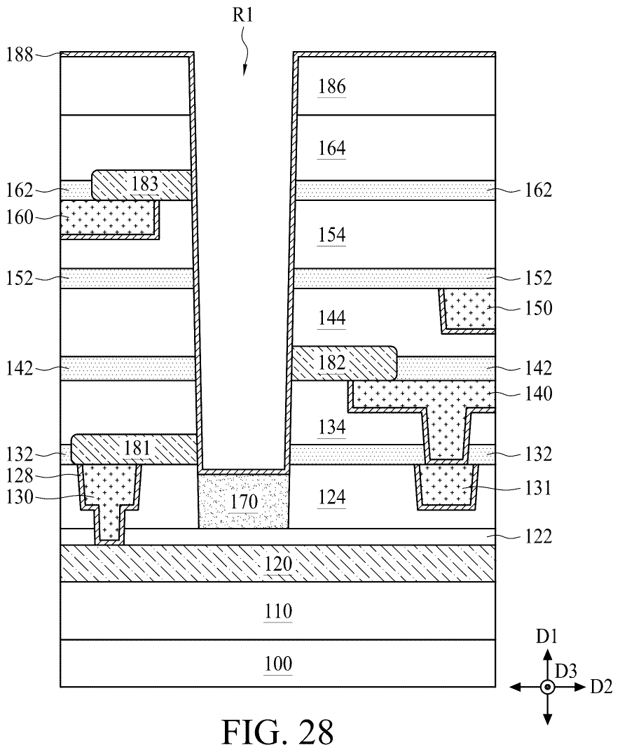

FIG. 1 is a flow diagram showing a method 200 for forming a semiconductor structure 10 with conductive through vias. FIGS. 2 to 30B are schematic cross-sectional, top or plan views illustrating sequential operations of the method 200 in FIG. 1. The method 200 includes a number of operations and the description and illustration are not deemed as a limitation to the sequence of the operations.

In operation 201 of FIG. 1, a device layer 110 is formed over a substrate 100, as shown in FIG. 2. The substrate 100 has a first surface S1 (or a front side S1) and a second surface S2 (or a back side S2) opposite to the first surface S1. The substrate 100 has a thickness along a first direction D1. The substrate 100 may be a semiconductor substrate such as a bulk silicon wafer. The substrate 10 includes at least one of silicon (Si), germanium (Ge), gallium (Ga), arsenic (As), phosphorus (P), indium (In), antimonide, SiGe, SiC, GaAs, GaN, GaP, InGaP, InP, InAs, InSb, GaAsP, AlInAs, AlGaAs, GaInAs, GaInP, GaInAsP, or other suitable materials. The substrate 100 may include any type of semiconductor body such as a silicon-on-insulator (SOI) substrate. Although not shown, the substrate 100 includes one or more semiconductor layers and/or epitaxial layers formed thereon. In some embodiments, the substrate 100 is implanted with dopants of a first conductivity type. In some embodiments, the first conductivity type is P type, and thus the substrate 100 is a P-type substrate.

In some embodiments, the substrate 100 includes multiple isolation structures 102. The isolation structures 102 may be shallow trench isolations (STIs). Although not specifically illustrated, the isolation structures 102 may be trenches filled with an insulating material. Appropriate wells (not shown) may be formed in the substrate 100 and separated by the isolation structures 102. In some embodiments, a P-well is formed in the substrate 100 where an N-type device, such as an N-type field-effect transistor (FET), is to be formed. In some embodiments, an N-well is formed in the substrate 100 where a P-type device, such as a P-type FET, is to be formed. In some embodiments, both a P-well and an N-well are formed in the substrate 100. The wells may be formed using an ion-implantation operation. P-type dopants such as boron (B), gallium (Ga) and indium (In), or N-type dopants such as phosphorous (P) and arsenide (As), may be implanted into selected regions of the substrate 100 using an implantation mask.

The device layer 110 is formed on the first surface S1 of the substrate 100. In some embodiments, the device layer 110 includes multiple transistors T10 surrounded by a dielectric layer 112. Although not specifically illustrated, the transistors T10 may be formed using one or more of lithography, etching, deposition, implantation, epitaxial growth, and planarization operations or the like. The transistors T10 may be separated by the isolation structures 102. Each transistor T10 includes a gate structure and its corresponding source/drain structures. The dielectric layer 112 may include silicon oxide (SiO₂), silicon nitride (SiN), undoped silicate glass (USG), phospho-silicate glass (PSG), boro-silicate glass (BSG), boron-doped phospho-silicate glass (BPSG), tetraethyl orthosilicate (TEOS), and/or any other low k dielectric materials. Multiple conductive contacts (not shown) may be respectively formed on the source structure, drain structure and gate structure of each transistor T10. The conductive contacts provide electrical connection between the transistors T10 and conductive structures that are subsequently formed over the transistors T10.

In operation 203 of FIG. 1, a conductive layer 120 is formed on the device layer 110, as shown in FIG. 3. In some embodiments, the conductive layer 120 is a metal layer electrically connected to the conductive contacts in the device layer 110. In some embodiments, the conductive layer 120 includes multiple metal features embedded in an inter-layer dielectric (ILD) layer. In some embodiments, the ILD layer includes silicon oxide, silicon nitride, and/or any other extreme low-k (ELK) dielectric materials, which have a dielectric constant between 2.0 and 3.0. The conductive layer 120 may be referred to as a zeroth metal (M0) layer. The M0 layer may be a local interconnect layer.

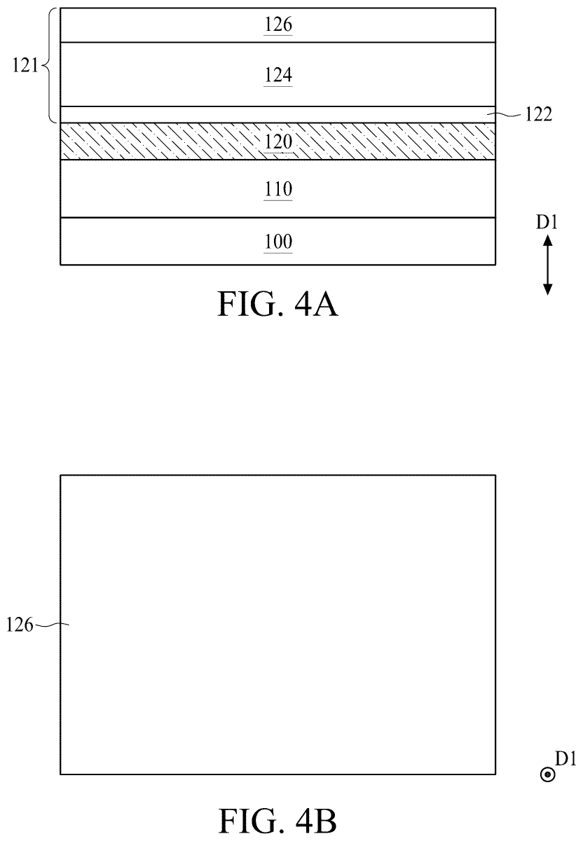

In operation 205 of FIG. 1, a multi-layer stack 121 is formed on the conductive layer 120, as shown in FIGS. 4A and 4B. FIG. 4B is a schematic top view of FIG. 4A. The multi-layer stack 121 includes an etch-stop layer (ESL) 122, a dielectric layer 124 and a hardmask layer 126.

The etch-stop layer (ESL) 122 is formed on the conductive layer 120. In some embodiments, the ESL 122 includes SiO₂, SiN, silicon carbide (SiC), silicon oxycarbide (SiOC), silicon carbon nitride (SiCN), silicon oxynitride (SiON), silicon oxycarbonitride (SiOCN), AlON, AlO, ZrO, or other suitable materials. The ESL 122 may be formed using spin coating, chemical vapor deposition (CVD), physical vapor deposition (PVD), atomic layer deposition (ALD), or other suitable methods. The ESL 122 may be formed under a temperature between about 20 degrees (°C) and about 400° C. In some embodiments, the ESL 122 has a thickness between about 10 angstroms (Å) and about 300 Å.

The dielectric layer 124 is deposited on the ESL 122. In some embodiments, the dielectric layer 124 includes SiO₂, SiN, SiC, SiOC, SiCN, SiON, SiOCN, or other suitable materials. The dielectric layer 124 may be formed using spin coating, CVD, PVD, ALD, or other suitable methods. In some embodiments, the dielectric layer 124 has a thickness between about 30 Å and about 2000 Å.

The hardmask layer 126 is formed on the dielectric layer 124. In some embodiments, the hardmask layer 126 includes SiO₂, SiN, SiC, SiOC, SiCN, SiON, SiOCN, W, WC, TiN, TiO, HfO, ZrO, ZnO, TiZrO, AlOₓ, AlON, or other suitable materials. The hardmask layer 126 may be formed using spin coating, CVD, PVD, ALD, or other suitable methods. The hardmask layer 126 may be formed under a temperature between about 50° C. and about 400° C. In some embodiments, the hardmask layer 126 has a thickness between about 30 Å and about 500 Å.

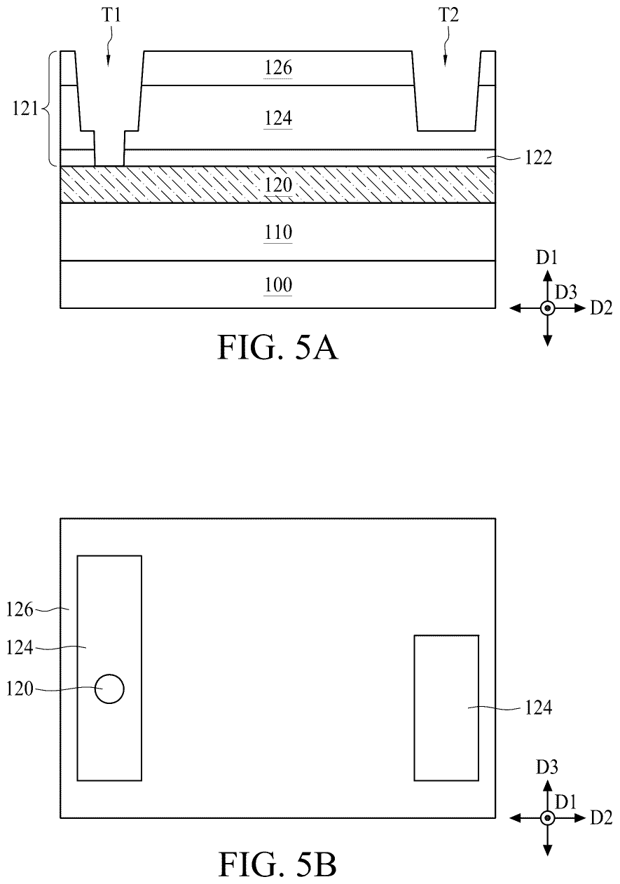

In operation 207 of FIG. 1, the multi-layer stack 121 is patterned to form a first trench T1 and a second trench T2, as shown in FIGS. 5A and 5B. FIG. 5B is a schematic top view of FIG. 5A. In some embodiments, the first and second trenches T1 and T2 are formed using a single or dual damascene technique including one or more lithographic and etching operations. The etching operation for patterning the multi-layer stack 121 may be a capacitively coupled plasma (CCP) etch, an inductively coupled plasma (ICP) etch, a remote plasma etch, or other suitable methods. In some embodiments, etching gases of the etching operation include CH₄, CH₃F, CH₂F₂, CHF₃, C₄F₈, C₄F₆, CF₄, NF₃, NH₃, NH₄F, H₂, HF, HBr, CO, CO₂, O₂, BCl₃, Cl₂, N₂, He, Ne, Ar, or the like. In some embodiments, the etching operation is performed under a pressure between about 0.2 millitorr (mT) and about 120 mT. In some embodiments, the etching operation is performed under a temperature between about 0 ° C. and about 180° C. In some embodiments, the etching operation uses a power between about 0 Watt (W) and about 3000 W. In some embodiments, the etching operation uses a bias voltage between about 0 Volts (V) and about 1200 V. One or more wet clean operations may be used to remove etch byproducts of the etching operation. After the etching operation, the hardmask layer 126 may be removed or stripped. However, in some embodiments, the hardmask layer 126 is remained on the dielectric layer 124 and is removed subsequently.

The first and second trenches T1 and T2 are arranged along a second direction D2 perpendicular to the first direction D1. The first and second trenches T1 and T2 extend along a third direction D3 perpendicular to the first direction D1 and the second direction D2. In some embodiments, the first trench T1 penetrates the multi-layer stack 121, while the second trench T2 extends to a predetermined depth of the dielectric layer 124, as shown in FIG. 5A. The first trench T1 exposes a portion of the underlying conductive layer 120.

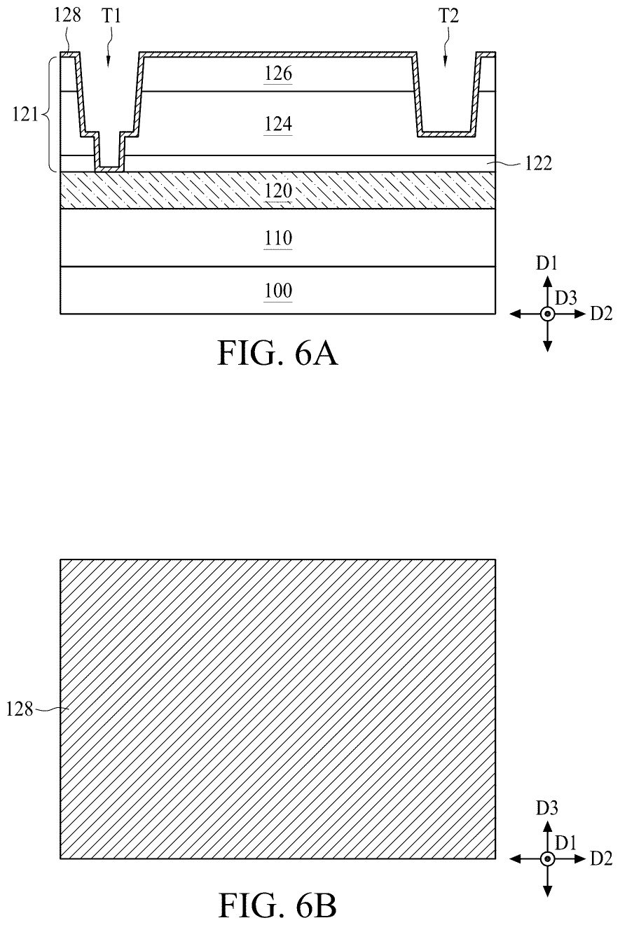

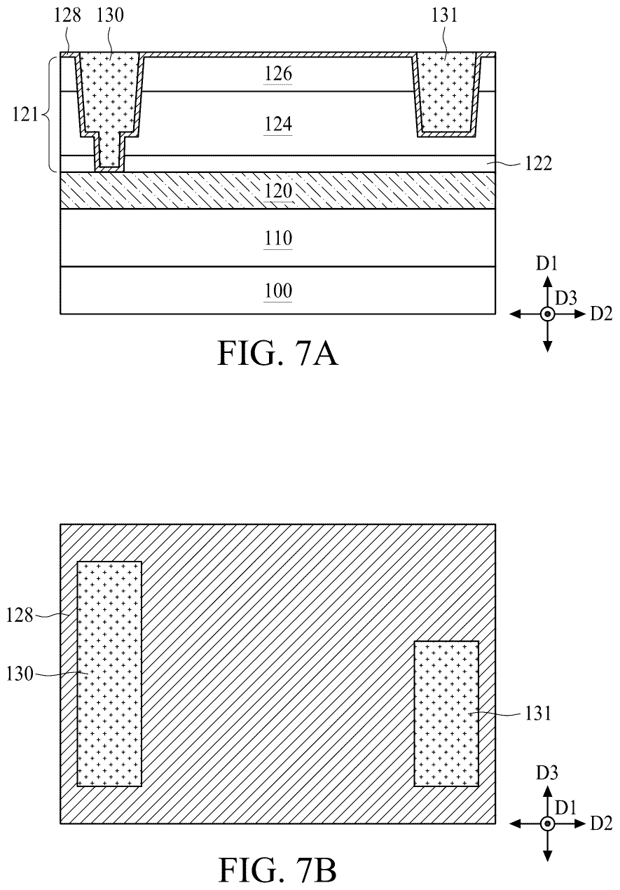

In operation 209 of FIG. 1, conductive structures 130 and 131 are formed over the conductive layer 120, as shown in FIGS. 6A, 6B, 7A and 7B. FIGS. 6B and 7B are schematic top views of FIGS. 6A and 7A, respectively. Referring to FIG. 6A, a barrier layer 128 is conformally formed in the first and second trenches T1 and T2. The barrier layer 128 may be formed using CVD, PVD, ALD, or other suitable methods. In some embodiments, the barrier layer 128 includes metal nitrides, metal carbide, metal oxide, or other suitable materials. In some embodiments, the barrier layer 128 has a thickness between about 5 Å and about 200 Å. In some embodiments, a portion of the barrier layer 128 is in contact with the conductive layer 120.

Referring to FIG. 7A, the first and second trenches T1 and T2 are filled with a conductive material such as tungsten (W), copper (Cu), cobalt (Co), aluminum (Al), nickel (Ni), tantalum (Ta), titanium (Ti), molybdenum (Mo), palladium (Pd), platinum (Pt), ruthenium (Ru), iridium (Ir), silver (Ag), gold (Au), tantalum nitride (TaN), titanium nitride (TiN), the like, or a combination thereof. The conductive material may be formed using sputtering, electroplating, PVD, ALD, or other suitable methods. The conductive material in the first and second trenches T1 and T2 forms the conductive structures 130 and 131, respectively. In some embodiments, the conductive structure 130 is electrically connected to the conductive layer 120. The layer where the conductive structures 130 and 131 resides may be referred to as a first metal (M1) layer. A planarization operation, such as chemical mechanical polishing (CMP), is used to remove excess conductive material and portions of the barrier layer 128. The hardmask layer 126 may be removed using the planarization operation. Thus, a top surface of the dielectric layer 124 is exposed.

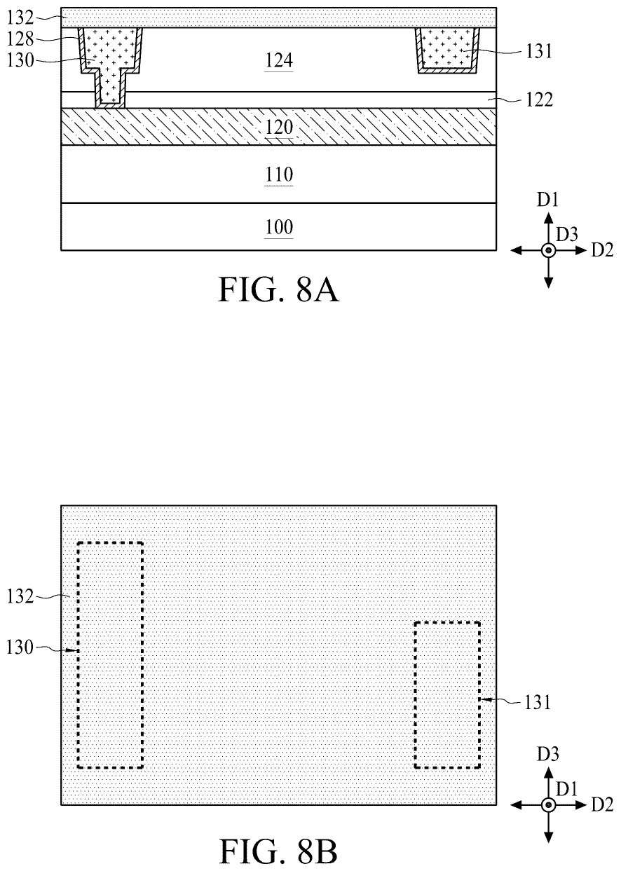

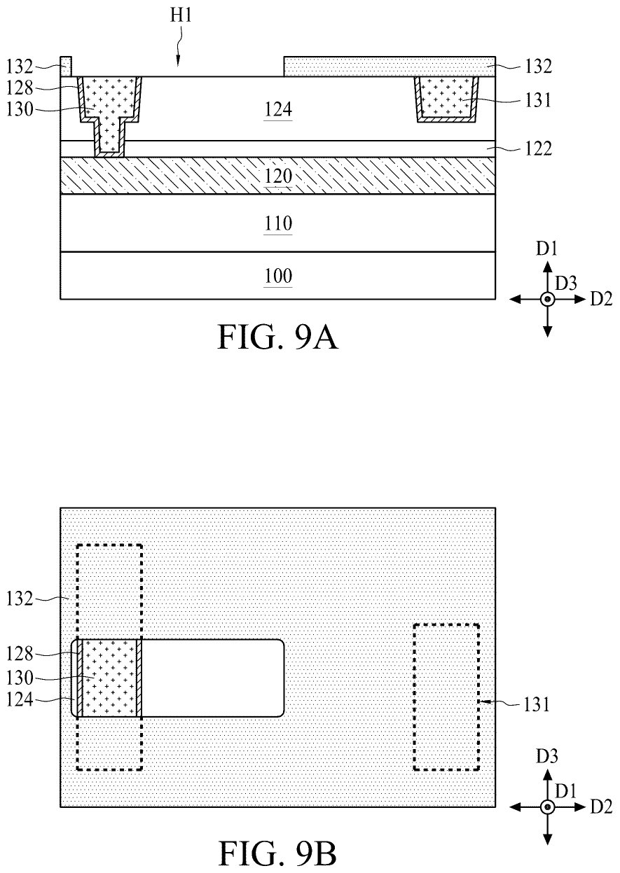

In operation 211 of FIG. 1, an ESL 132 is deposited on the conductive structures 130 and 131, as shown in FIGS. 8A, 8B, 9A and 9B. FIGS. 8B and 9B are schematic top views of FIGS. 8A and 9A, respectively. Referring to FIG. 8A, the ESL 132 may be formed on the dielectric layer 124 and the conductive structures 130 and 131 using spin coating, CVD, PVD, ALD, or other suitable methods. The ESL 132 may include a material the same as or similar to that of the ESL 122.

Referring to FIG. 9A, a portion of the ESL 132 is removed to form a hole H1 using an etching operation. In some embodiments, the hole H1 exposes the conductive structure 130 and a portion of the dielectric layer 124.

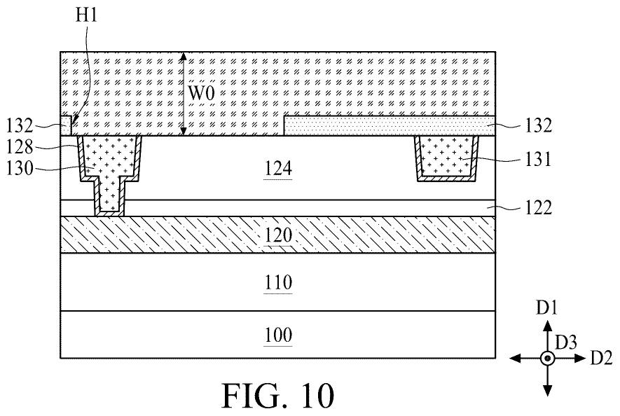

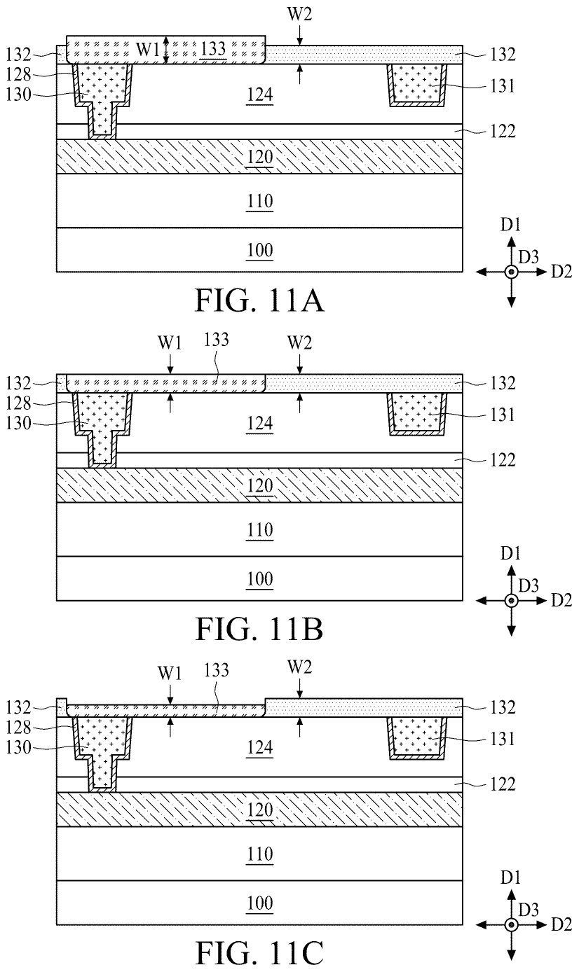

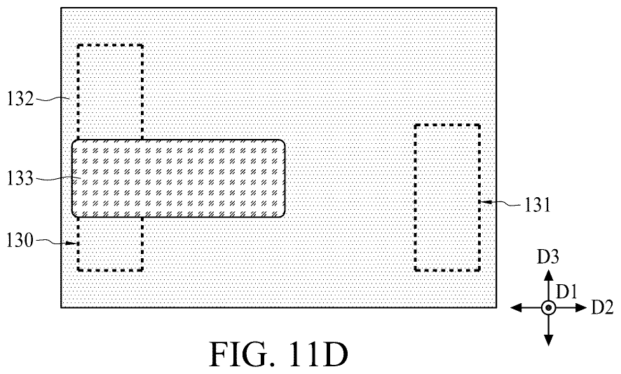

In operation 213 of FIG. 1, a filling member 133 is formed in the hole H1 defined by the ESL 132, as shown in FIGS. 10 and 11A to 11D. FIG. 11D is a schematic top view of FIG. 11A, 11B or 11C. Referring to FIG. 10, a filling material is deposited into the hole H1 using spin coating, CVD, PVD, electroplating, or other suitable methods. The filling material covers the dielectric layer 124, the barrier layer 128, the conductive structure 130 and the ESL 132. In some embodiments, the filling material includes Si, SiO₂, SiN, SiC, SiOC, SiCN, SiON, SiOCN, metal nitrides, metal carbide, metal oxide, metals, or other suitable materials. In some embodiments, the filling material has a thickness W0 between about 30 Å and about 1000 Å. The filling material may be referred to as a reverse material.

Referring to FIGS. 11A to 11D, the filling material is patterned to form the filling member 133 using an etching operation or a CMP operation. In some embodiments, the filling member 133 is thinned, and portions of the filling member 133 directly over the ESL 132 are removed. Therefore, the filling member 133 is formed in the hole H1 and laterally surrounded by the ESL 132. In some embodiments, the filling member 133 covers and contacts the conductive structure 130. In some embodiments, the thinned filling member 133 has a thickness W1 between about 10 Å and about 300 Å. In some embodiments, the thickness W1 is greater than a thickness W2 of the ESL 132, as shown in FIG. 11A. In other embodiments, the thickness W1 is substantially equal to or less than the thickness W2, as shown in FIGS. 11B and 11C, respectively.

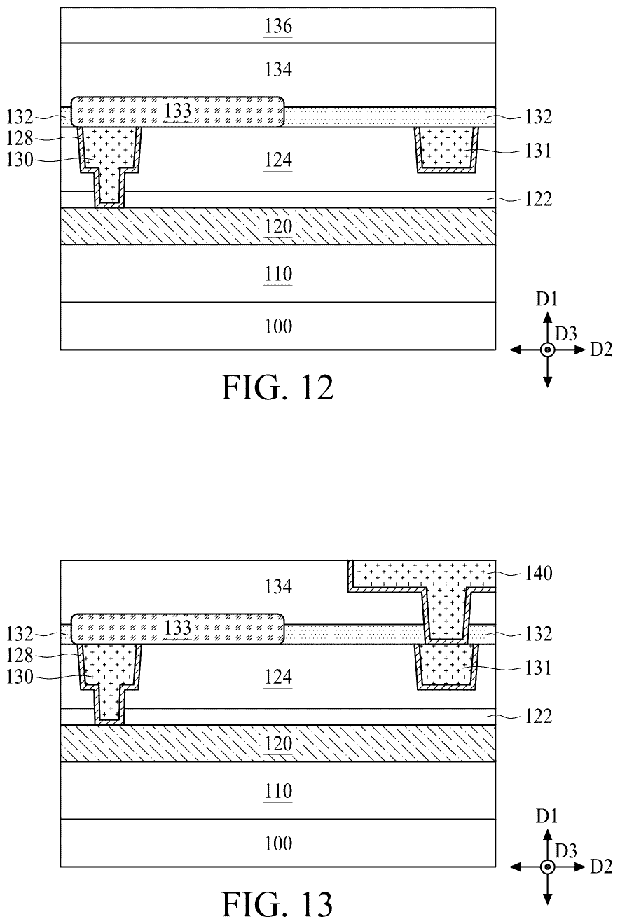

Operations 205, 207, 209, 211 and 213 may be repeatedly performed according to design requirements. FIGS. 12 to 17 are schematic cross-sectional views illustrating operations 205, 207, 209, 211 and 213 of the method 200.

Referring to FIG. 12, the operation performed with reference to FIG. 12 is similar to that performed with reference to FIG. 4A. In some embodiments, a dielectric layer 134 is deposited on the ESL 132 and the filling member 133, and a hardmask layer 136 is formed on the dielectric layer 134. The dielectric layer 134 and the hardmask layer 136 may be formed using similar operations described with reference to FIG. 4A (i.e., Operation 205). Materials of the dielectric layer 134 and the hardmask layer 136 may be the same as or similar to those of the dielectric layer 124 and the hardmask layer 126, respectively.

Referring to FIG. 13, a newly formed feature shown in FIG. 13 is similar to that shown in FIG. 7A. In some embodiments, a conductive structure 140 is formed over and electrically connected to the conductive structure 131. The conductive structure 140 may be formed using similar operations described in FIGS. 5A, 6A and 7A (i.e., Operations 207 and 209). The material of the conductive structure 140 may be the same as or similar to that of the conductive structure 130 or 131. The conductive structure 140 may be referred to as a second metal (M2) layer.

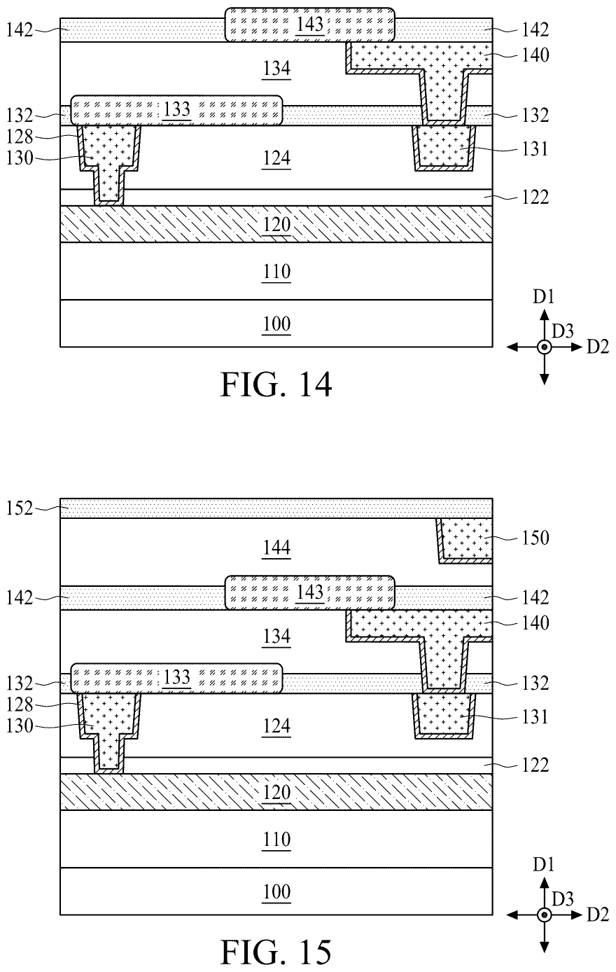

Referring to FIG. 14, a newly formed feature shown in FIG. 14 is similar to that shown in FIG. 11A. In some embodiments, a filling member 143 is formed on the dielectric layer 134 and the conductive structure 140. The filling member 143 is laterally surrounded by an ESL 142. In some embodiments, the filling member 143 is at least in contact with the conductive structure 140. The ESL 142 and the filling member 143 may be formed using similar operations described in FIGS. 8A, 9A, 10 and 11A (i.e., Operations 211 and 213). Materials of the ESL 142 and the filling member 143 may be the same as or similar to those of the ESL 132 and the filling member 133, respectively.

Referring to FIG. 15, a dielectric layer 144 is deposited on the ESL 142 and the filling member 143. A conductive structure 150 is then formed in the dielectric layer 144 and over the conductive structure 140. The conductive structure 150 may be referred to as a third metal (M3) layer. Subsequently, an ESL 152 is formed on the dielectric layer 144 and the conductive structure 150. Materials of the dielectric layer 144, the conductive structure 150 and the ESL 152 may be the same as or similar to those of the dielectric layer 124, the conductive structure 130 and the ESL 122, respectively.

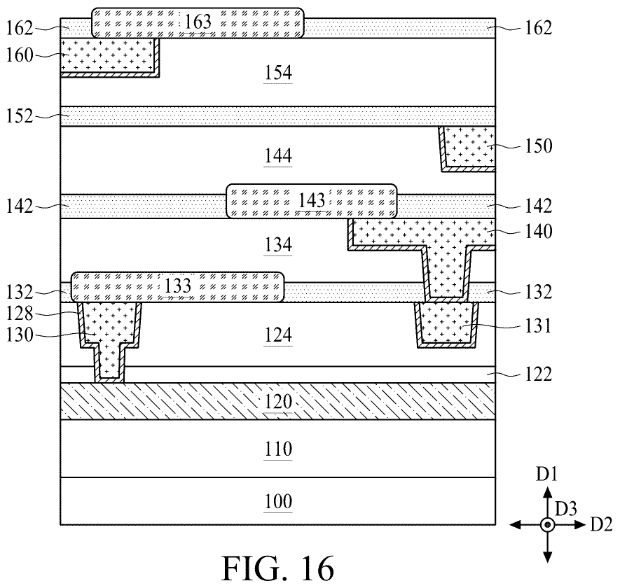

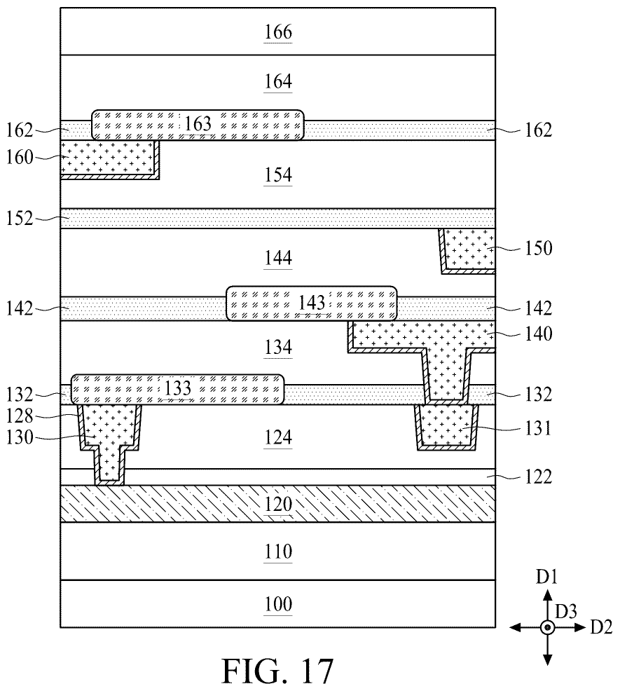

Referring to FIG. 16, a dielectric layer 154 is deposited on the ESL 152. A conductive structure 160 is then formed in the dielectric layer 154 and over the conductive structure 130. The conductive structure 160 may be referred to as a fourth metal (M4) layer. Subsequently, a filling member 163 is formed on the dielectric layer 154 and the conductive structure 160. The filling member 163 is surrounded by an ESL 162. In some embodiments, the filling member 163 is at least in contact with the conductive structure 160. The ESL 162 and the filling member 163 may be formed using similar operations described in FIGS. 8A, 9A, 10A and 11A (i.e., Operations 211 and 213). Materials of the dielectric layer 154, the conductive structure 160, the ESL 162 and the filling member 163 may be the same as or similar to those of the dielectric layer 124, the conductive structure 130, the ESL 122 and the filling member 133, respectively. In some embodiments, the filling members 133, 143 and 163 have substantially the same thickness.

Referring to FIG. 17, a newly formed feature shown in FIG. 17 is similar to that shown in FIG. 4A or 12. In some embodiments, a dielectric layer 164 is deposited on the ESL 162 and the filling member 163, and a hardmask layer 166 is formed on the dielectric layer 164. The dielectric layer 164 and the hardmask layer 166 may be formed using similar operations described in FIG. 4A (i.e., Operation 205). Materials of the dielectric layer 164 and the hardmask layer 166 may be the same as or similar to those of the dielectric layer 124 and the hardmask layer 126, respectively.

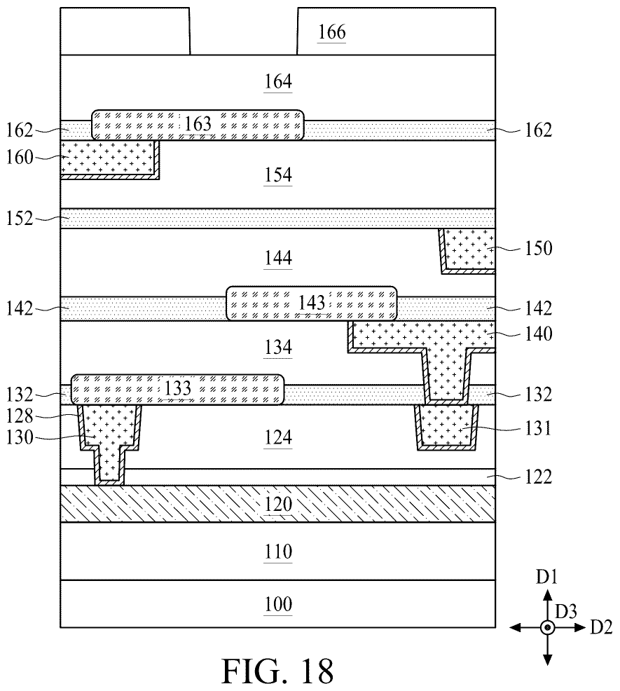

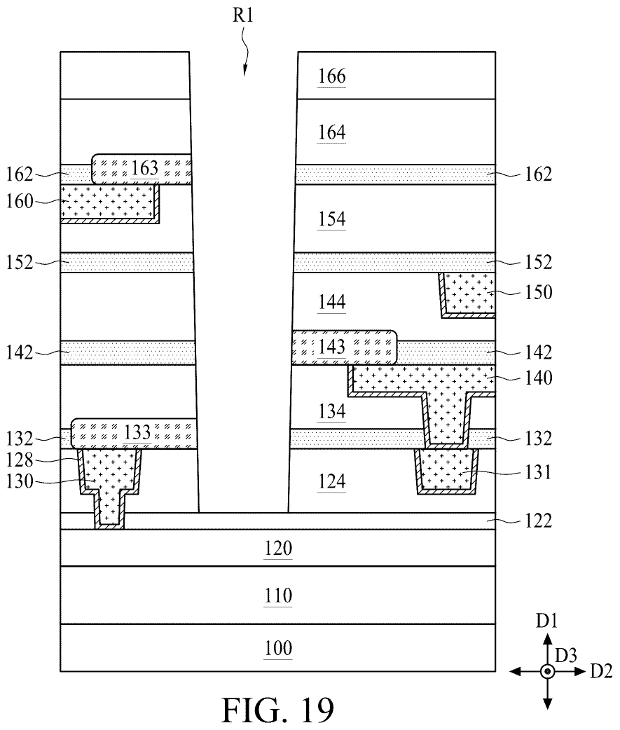

In operation 215 of FIG. 1, a through via R1 is formed penetrating the filling members 133, 143 and 163, as shown in FIGS. 18 and 19. Referring to FIG. 18, in some embodiments, the hardmask layer 166 is patterned using a photoresist pattern (not shown) formed thereon.

Referring to FIG. 19, in some embodiments, one or more etching operations are performed on the dielectric layers 124, 134, 144, 154 and 164, the ESLs 132, 142, 152 and 162, and the filling members 133, 143 and 163 using the patterned hardmask layer 166 as an etch mask. The etching operation stops until the bottommost ESL 122 is exposed, and thereby forming the through via R1. In some embodiments, the through via R1 extends along the first direction D1. In some embodiments, the filling members 133, 143 and 163 are cut by the through via R1. That is, portions of the filling members 133, 143 and 163 are removed during the formation of the through via R1. The through via R1 exposes side surfaces of the filling members 133, 143 and 163. The through via R1 may be referred to as a convergent via.

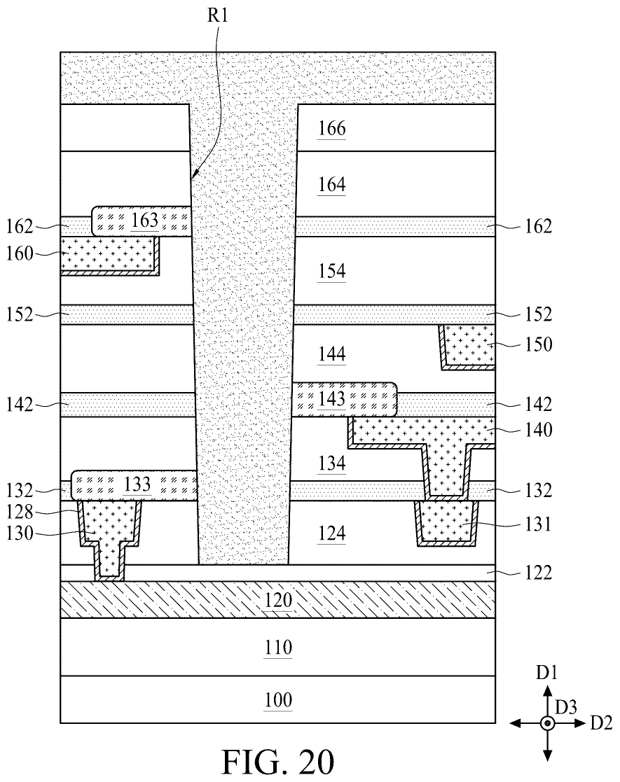

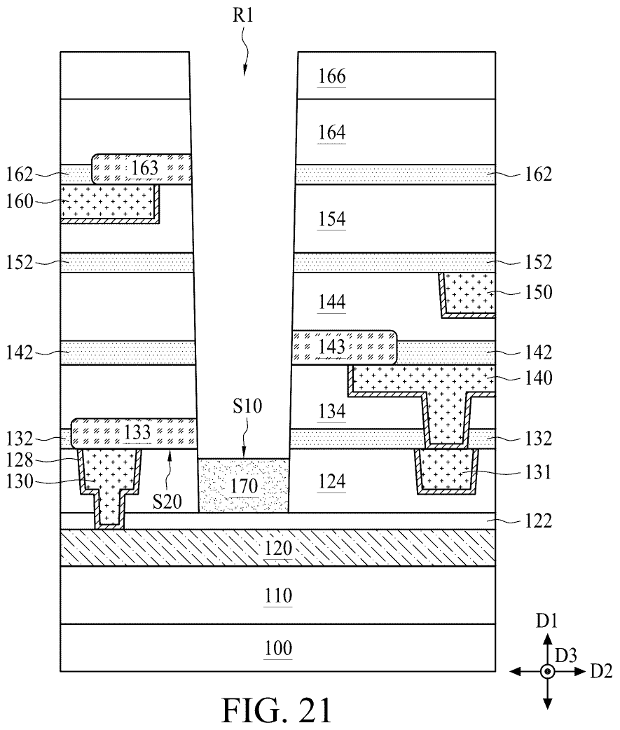

In operation 217 of FIG. 1, an isolating member 170 is formed in the through via R1, as shown in FIGS. 20 and 21. Referring to FIG. 20, a dielectric material is deposited into the through via R1 using spin coating, CVD, PVD, ALD, or other suitable methods. In some embodiments, the dielectric material includes SiO₂, SiN, SiC, SiOC, SiCN, SiON, SiOCN, or other suitable materials. Excess dielectric material over the hardmask layer 166 may be removed.

Referring to FIG. 21, in some embodiments, an etch-back operation is performed on the dielectric material. Most of the dielectric material is removed while a portion of the dielectric material is left at the bottom of the through via R1, thus forming the isolating member 170. At this stage, the through via R1 is re-formed, and the filling members 133, 143 and 163 are re-exposed through the through via R1. In some embodiments, a top surface S10 of the isolating member 170 is lower than a bottom surface S20 of the filling member 133. That is, the side surface of the filling member 133 is not blocked by the isolating member 170.

In some embodiments, the isolating member 170 is disposed on the ESL 122. The isolating member 170 is used to physically and electrically separate the conductive layer 120 from a conductive member subsequently formed on the isolating member 170.

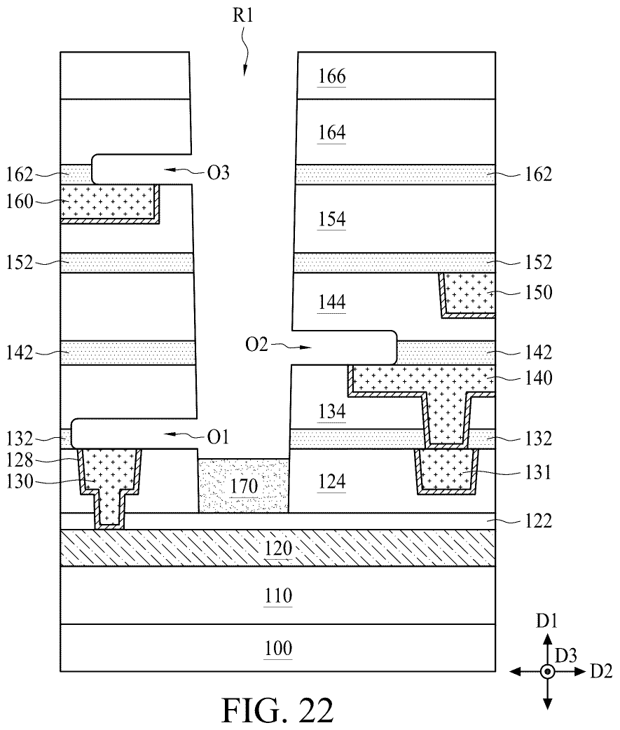

In operation 219 of FIG. 1, a selective etching operation is performed on the filling members 133, 143 and 163, as shown in FIG. 22. The selective etching operation is specific to the filling members 133, 143 and 163. In some embodiments, the selective etching operation may horizontally etch the filling members 133, 143 and 163 to form openings O1, O2 and O3, respectively. The etch-back operation and the selective etching operation may be a CCP etch, an ICP etch, a remote plasma etch, or other suitable methods. In some embodiments, etching gases of the etch-back operation and the selective etching operation include CH₄, CH₃F, CH₂F₂, CHF₃, C₄F₈, C₄F₆, CF₄, NF₃, NH₃, NH₄F, H₂, HF, HBr, CO, CO₂, O₂, BCl₃, Cl₂, N₂, He, Ne, Ar, or the like. In some embodiments, the etch-back operation and the selective etching operation are performed under a pressure between about 0.2 mT and about 120 mT. In some embodiments, the etch-back operation and the selective etching operation are performed under a temperature between about 0° C. and about 166° C. In some embodiments, the etch-back operation and the selective etching operation use a power between about 0 W and about 3000 W. In some embodiments, the etch-back operation and the selective etching operation use a bias voltage between about 0 V and about 1200 V. One or more wet clean operations may be used to remove etch-byproducts of the etch-back operation and the selective etching operation. In some embodiments, the openings O1, O2 and O3 are respectively communicated with the through via R1.

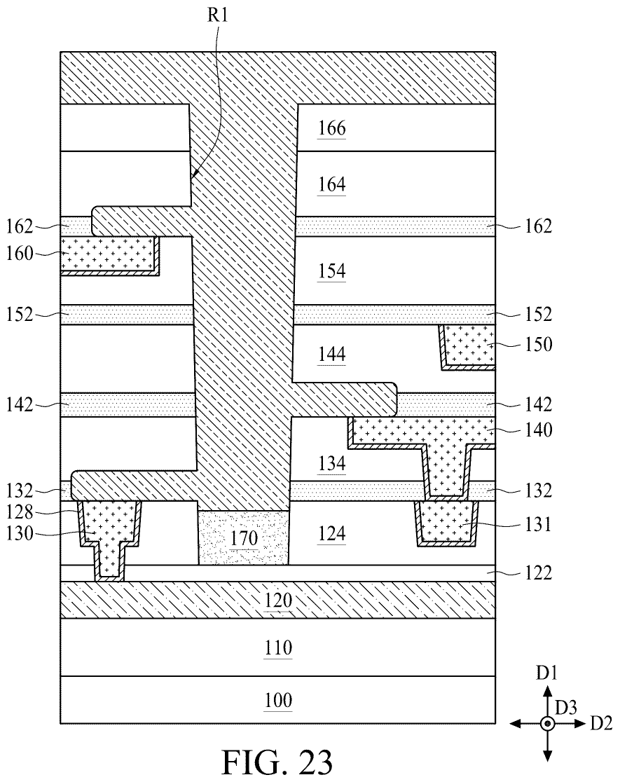

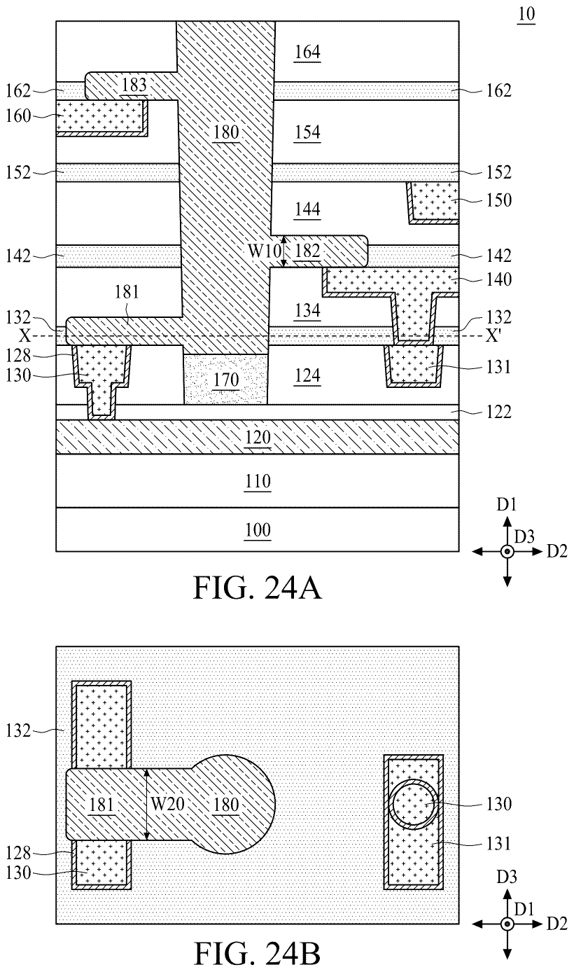

In operation 221 of FIG. 1, a first conductive member 180 and multiple second conductive members 181, 182 and 183 are formed, as shown in FIGS. 23, 24A and 24B. Referring to FIG. 23, a conductive material is deposited into the through via R1 using sputtering, electroplating, PVD, ALD, or other suitable methods. In some embodiments, the conductive material fills the openings O1, O2 and O3. The conductive material may include W, Cu, Co, Al, Ni, Ta, Ti, Mo, Pd, Pt, Ru, Ir, Ag, Au, TaN, TiN, the like, or a combination thereof.

Referring to FIG. 24A, a planarization operation, such as CMP, is used to remove a portion of the conductive material over a top surface of the dielectric layer 164, thus forming the first conductive member 180 and the second conductive members 181, 182 and 183 connected to the first conductive member 180. The first conductive member 180 may be referred to as a conductive through via. The second conductive members 181, 182 and 183 are branched from the first conductive member 180 and may be referred to as branch portions of the conductive through via. In some embodiments, the first conductive member 180 is formed on the isolating member 170. The hardmask layer 166 may be removed during the planarization operation or using other suitable methods. In some embodiments, the first conductive member 180 extends along the first direction D1 and penetrates the dielectric layers 164, 154, 144 and 134. In some embodiments, the second conductive members 181, 182 and 183 extend along the second direction D2 or the third direction D3. The second conductive members 181, 182 and 183 may be referred to as horizontal conductive vias or short-cut vias. In some embodiments, the second conductive member 181, 182 or 183 has a thickness W10 between about 10 Å and about 300 Å. In some embodiments, the second conductive members 181, 182 and 183 are electrically connected to the conductive structures 130, 140 and 160, respectively. The number of second conductive members are configurable according to the number of filling members disposed on respective metal layers (for example, M1 to M4 or higher metal layers). At this stage, the formation of the semiconductor structure 10 with the first conductive member 180 and the second conductive members 181, 182 and 183 connected to the first conductive member 180 is completed.

FIG. 24B is a plan view along line X-X′ in FIG. 24A. In some embodiments, the second conductive member 181, 182 or 183 has a width W20 between about 50 Å and about 800 Å. Referring to FIGS. 24A and 24B, in some embodiments, the first conductive member 180 is not laterally surrounded by any barrier layer or liner which includes non-conductors. In such embodiments, electrical resistance of the first conductive member 180 can be decreased because the first conductive member 180 is made of conductive materials such as metals.

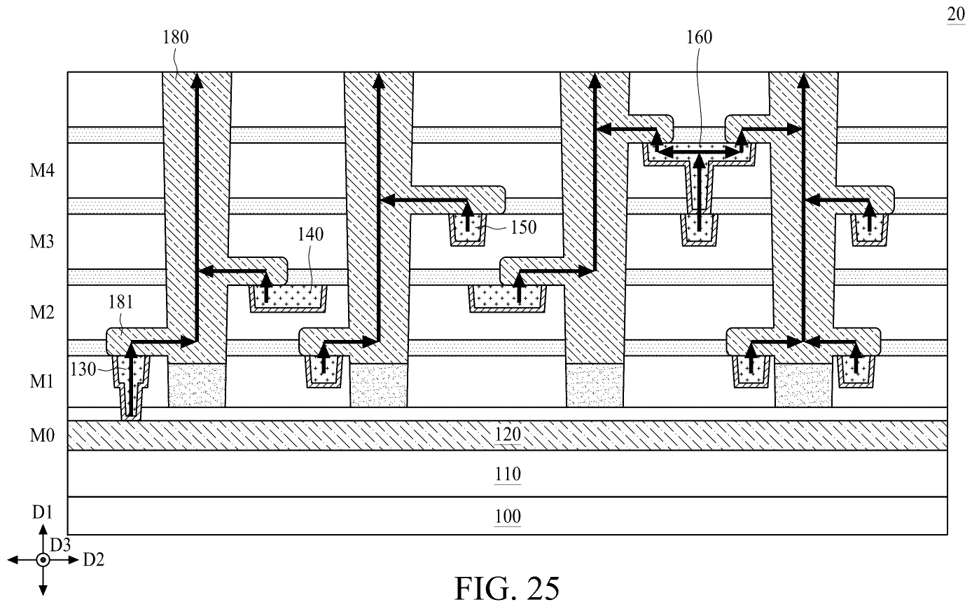

FIG. 25 shows a semiconductor structure 20 including multiple first conductive members 180 extending vertically and multiple second conductive members extending horizontally (such as the second conductive members 181). The semiconductor structure 20 is similar to the semiconductor structure 10 in FIG. 24A. In some embodiments, the first conductive members 180 is electrically connected to the metal layers (for example, M1 to M4) through the second conductive members. The arrows show directions of current flowing in the semiconductor structure 20. In some embodiments, the method 200 for forming the semiconductor structure 10 or 20 simplifies parts of conventional processes such as the dual damascene technique used for forming stacked metal lines and vias. In addition, the method 200 can be combined with the dual damascene technique to form different configurations of interconnect structures, thus increasing process flexibility.

In some embodiments, if a barrier layer or liner is required to be disposed in the semiconductor structure 10 due to a concern such as preventing metal diffusion, the procedure of forming the semiconductor structure 10 can be further revised to take the formation of the barrier layer or liner into account.

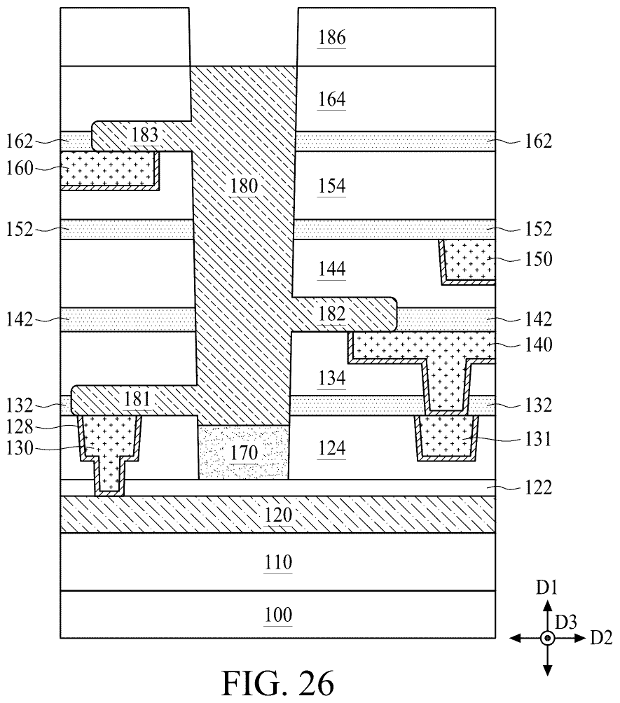

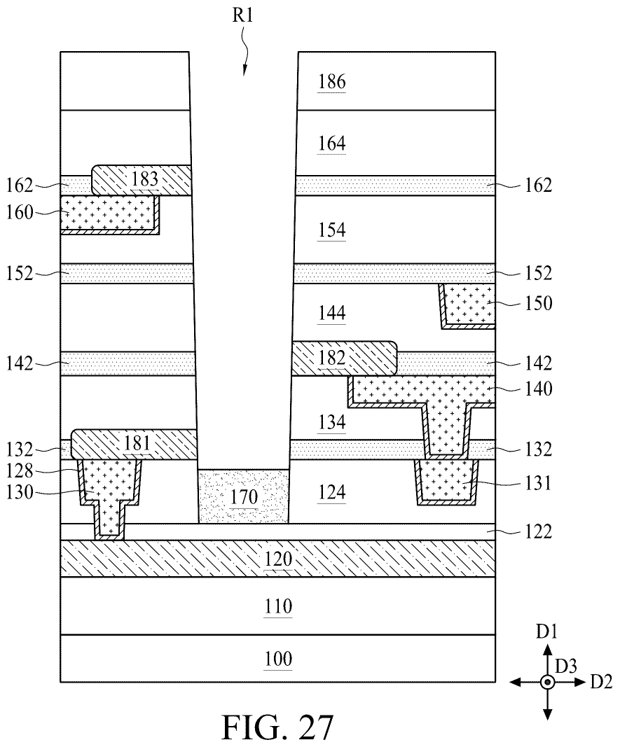

In operation 223 of FIG. 1, a portion of the first conductive member 180 is removed, as shown in FIGS. 26 and 27. Referring to FIG. 26, a hardmask pattern 186 is formed on the dielectric layer 164. In some embodiments, the hardmask pattern 186 exposes the first conductive member 180.

Referring to FIG. 27, in some embodiments, a metal reactive-ion etch (RIE) operation is performed on the first conductive member 180. The metal RIE may partially or completely remove the first conductive member 180, while substantially not consuming the second conductive members 181, 182 and 183. The metal RIE operation may be a CCP etch, an ICP etch, a remote plasma etch, or other suitable methods. In some embodiments, etching gases of the metal RIE operation include CH₄, CH₃F, CH₂F₂, CHF₃, C₄F₈, C₄F₆, CF₄, NF₃, NH₃, NH₄F, H₂, HF, HBr, CO, CO₂, O₂, BCl₃, Cl₂, N₂, He, Ne, Ar, or the like. In some embodiments, the metal RIE operation is performed under a pressure between about 0.2 mT and about 120 mT. In some embodiments, the metal RIE operation is performed under a temperature between about 0 ° C. and about 166° C. In some embodiments, the metal RIE operation uses a power between about 0 W and about 3000 W. In some embodiments, the metal RIE operation uses a bias voltage between about 0 V and about 1200 V. One or more wet clean operations may be used to remove etch-byproducts of the metal RIE operation. The first conductive member 180 is removed while the second conductive members 181, 182 and 183 remain. At this stage, the through via R1 is re-formed, and the second conductive members 181, 182 and 183 are exposed through the through via R1.

In operation 225 of FIG. 1, a barrier layer 188 is conformally formed in the through via R1. The barrier layer 188 may be formed using CVD, PVD, ALD, or other suitable methods. In some embodiments, the barrier layer 188 includes metal nitrides, metal carbide, metal oxide, or other suitable materials. In some embodiments, the barrier layer 188 has a thickness between about 5 Å and about 200 Å. In some embodiments, portions of the barrier layer 188 are respectively in contact with the isolating member 170, and the second conductive members 181, 182 and 183.

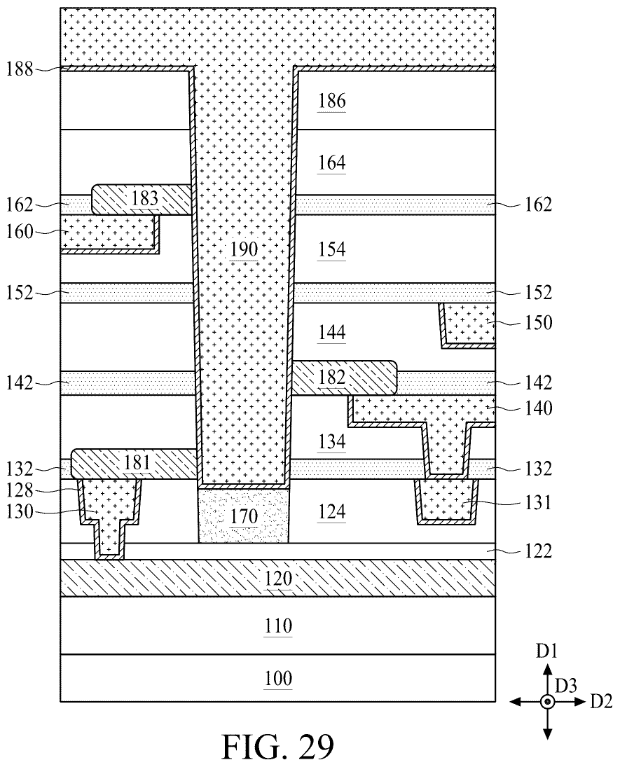

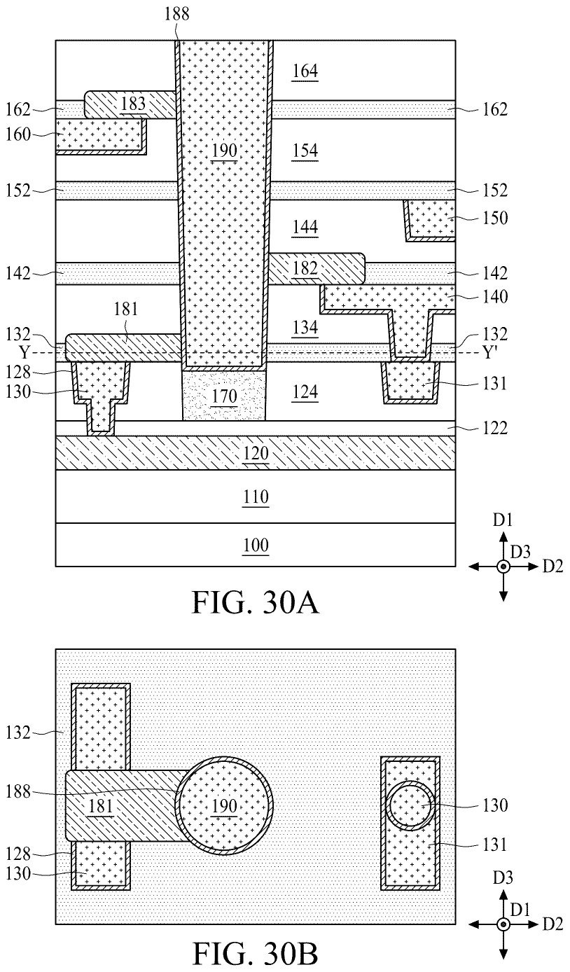

In operation 227 of FIG. 1, a third conductive member 190 is formed on the barrier layer 188, as shown in FIGS. 29, 30A and 30B. Referring to FIG. 29, a conductive material is deposited into the through via R1 using sputtering, electroplating, PVD, ALD, or other suitable methods. In some embodiments, the conductive material fills the through via R1. The conductive material may include W, Cu, Co, Al, Ni, Ta, Ti, Mo, Pd, Pt, Ru, Ir, Ag, Au, TaN, TiN, the like, or a combination thereof.

Referring to FIG. 30A, a planarization operation, such as CMP, is used to remove a portion of the conductive material over a top surface of the dielectric layer 164, thus forming the third conductive member 190. In some embodiments, the third conductive member 190 is a conductive through via. The hardmask pattern 186 and portions of the barrier layer 188 may be removed during the planarization operation or using other suitable methods. In some embodiments, the third conductive member 190 extends along the first direction D1 and penetrates the dielectric layers 164, 154, 144 and 134. In some embodiments, the second conductive members 181, 182 and 183 are electrically connected to the barrier layer 188 and further to the third conductive member 190. At this stage, the formation of a semiconductor structure 20 with the third conductive member 190 is complete.

FIG. 30B is a plan view along line Y-Y′ in FIG. 30A. In some embodiments, the third conductive member 190 is laterally surrounded by the barrier layer 188.

The present disclosure provides a semiconductor structure with one or more conductive through vias. The conductive through via extends vertically and penetrates multiple dielectric layers. The conductive through via is simultaneously electrically connected to multiple conductive structures respectively disposed at the dielectric layers at different levels via its branch portions. The conductive through via and the branch portions are free from any barrier layer or liner which includes a non-conductor such as nitrogen (N). Therefore, electrical resistance of the conductive through via and the branch portions can be decreased because they are made of substantially pure metals. A resistive-capacitive delay (RC delay) of the semiconductor structure can be reduced. Besides, the method for forming the semiconductor structure provided by the present disclosure employs disposing a filling member that extends horizontally, followed by removing the filling member using a selective etching operation. Such method can eliminate a need of multiple etching and lithography processes.

One aspect of the present disclosure provides a method of forming a semiconductor structure. The method includes: forming a conductive layer on a device layer; forming a multi-layer stack on the conductive layer; patterning the multi-layer stack to form a trench; forming a conductive structure in the trench; depositing an etch stop layer (ESL) on the conductive structure; forming a hole in the ESL, wherein the hole exposes the conductive structure; forming a filling member in the hole, wherein the filling member is disposed on the conductive structure; forming a through via cutting the filling member; and filling the through via with a conductive material to form a first conductive member.

One aspect of the present disclosure provides another method of forming a semiconductor structure. The method includes: forming a conductive layer over a substrate; forming a dielectric layer and a conductive structure surrounded by the dielectric layer over the conductive layer; forming an ESL and a filling member surrounded by the ESL on the dielectric layer, wherein the filling member is disposed on the conductive structure; forming a through via penetrating the dielectric layer and exposing a side surface of the filling member; forming an isolating member in the through via, wherein a top surface of the isolating member is lower than a bottom surface of the filling member; horizontally etching the filling member from the through via to form an opening communicated with the through via; and filling the through via and the opening with conductive material to respectively form a first conductive member and a second conductive member.

Another aspect of the present disclosure provides a semiconductor structure. The semiconductor structure includes: a conductive layer, disposed over a substrate; a first conductive structure, disposed over the conductive layer; an isolating member, disposed over the conductive layer and separated from the first conductive structure, wherein the first conductive structure and the isolating member are surrounded by a first dielectric layer; a first conductive member, disposed on isolating member; and a second conductive member, disposed on the first conductive structure and the first dielectric layer. The first conductive member and the first conductive structure extend along a first direction. The second conductive member extends along a second direction perpendicular to the first direction.

The foregoing outlines features of several embodiments so that those skilled in the art may better understand the aspects of the present disclosure. Those skilled in the art should appreciate that they may readily use the present disclosure as a basis for designing or modifying other operations and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

Moreover, the scope of the present application is not intended to be limited to the particular embodiments of the process, machine, manufacture, and composition of matter, means, methods and steps described in the specification. As one of ordinary skill in the art will readily appreciate from the disclosure of the present invention, processes, machines, manufacture, compositions of matter, means, methods or steps, presently existing or later to be developed, that perform substantially the same function or achieve substantially the same result as the corresponding embodiments described herein be utilized according to the present invention. Accordingly, the appended claims are intended to include within their scope such processes, machines, manufacture, compositions of matter, means, methods and steps.

1. A method of forming a semiconductor structure, comprising:
forming a conductive layer on a device layer;
forming a multi-layer stack on the conductive layer;
patterning the multi-layer stack to form a trench;
forming a conductive structure in the trench;
depositing an etch stop layer (ESL) on the conductive structure;
forming a hole in the ESL, wherein the hole exposes the conductive structure;
forming a filling member in the hole, wherein the filling member is disposed on the conductive structure;
forming a through via cutting the filling member; and
filling the through via with a conductive material to form a first conductive member.

2. The method of claim 1, wherein the removing of the filling member is performed by a selective etching configured to horizontally etch the filling member.

3. The method of claim 1, wherein a top surface of the isolating member is lower than a top surface of the conductive structure.

4. The method of claim 1, wherein a thickness of the filling member is greater or less than a thickness of the ESL.

5. The method of claim 1, wherein a thickness of the filling member is substantially equal to a thickness of the ESL.

6. The method of claim 1, wherein the filling member is made of Si, SiO₂, SiN, SiC, SiOC, SiCN, SiON, SiOCN, metal nitrides, metal carbide, metal oxide or metals.

7. The method of claim 1, after the forming of the through via, further comprising:
forming an isolating member in the through via; and
removing the filling member to form an opening communicated with the through via.

8. The method of claim 7, further comprising:
filling the opening with the conductive material to form a second conductive member connected with the first conductive member, wherein
the first conductive member extends along a first direction, and
the second conductive member extends along a second direction perpendicular to the first direction.

9. The method of claim 8, wherein the first conductive member is electrically connected to the conductive structure by the second conductive member.

10. A method of forming a semiconductor structure, comprising:
forming a conductive layer over a substrate;
forming a dielectric layer and a conductive structure surrounded by the dielectric layer over the conductive layer;
forming an ESL and a filling member surrounded by the ESL on the dielectric layer, wherein the filling member is disposed on the conductive structure;
forming a through via penetrating the dielectric layer and exposing a side surface of the filling member;
forming an isolating member in the through via, wherein a top surface of the isolating member is lower than a bottom surface of the filling member;
horizontally etching the filling member from the through via to form an opening communicated with the through via; and
filling the through via and the opening with conductive material to respectively form a first conductive member and a second conductive member.

11. The method of claim 10, wherein
the first conductive member extends along a first direction,
the second conductive member extends along a second direction perpendicular to the first direction, and
the first conductive member is connected with the second conductive member.

12. The method of claim 11, further comprising:
removing the first conductive member to re-form the through via;
conformally forming a barrier layer in the re-formed through via; and
depositing conductive material on the barrier layer to form a third conductive member.

13. The method of claim 12, wherein the removing of the first conductive member is performed by a metal reactive-ion etch which is performed under a pressure between about 0.2 millitorr (mT) and about 120 mT, and under a temperature between about 0° C. and about 166 °C.

14. The method of claim 12, wherein
the barrier layer includes metal nitrides, metal carbide or metal oxide, and
the third conductive member is electrically connected to the second conductive member via the barrier layer.

15. The method of claim 12, wherein
the third conductive member is disposed over the isolating member, and
the third conductive member is separated from the isolating member and the second conductive member by the barrier layer.

16. A semiconductor structure, comprising:
a conductive layer, disposed over a substrate;
a first conductive structure, disposed over the conductive layer;
an isolating member, disposed over the conductive layer and separated from the first conductive structure, wherein the first conductive structure and the isolating member are surrounded by a first dielectric layer;
a first conductive member, disposed on isolating member; and
a second conductive member, disposed on the first conductive structure and the first dielectric layer, wherein
the first conductive member and the first conductive structure extend along a first direction, and
the second conductive member extends along a second direction perpendicular to the first direction.

17. The semiconductor structure of claim 16, wherein the second conductive member electrically couples the first conductive structure to the first conductive member.

18. The semiconductor structure of claim 16, further comprising:
an ESL disposed on the conductive layer, wherein the isolating member is separated from the conductive layer by the ESL.

19. The semiconductor structure of claim 16, further comprising:
a second dielectric layer, disposed over the first dielectric layer;
a second conductive structure, surrounded by the second dielectric layer; and
a third conductive member, covering a portion of the second conductive structure and extending along the second direction.

20. The semiconductor structure of claim 19, wherein the third conductive member electrically couples the second conductive structure to the first conductive member.
